(19) United States
(12) Patent Application Publication
(10) Pub. No.: US 2022/0320831 A1
(43) Pub. Date: Oct. 6, 2022

(54) Optical Device

(71) Applicant: Nippon Telegraph and Telephone Corporation, Tokyo (JP)

(72) Inventors: Takuma Tsurugaya, Tokyo (JP); Takuro Fujii, Tokyo (JP); Takaaki Kakitsuka, Tokyo (JP); Shinji Matsuo, Tokyo (JP)

(21) Appl. No.: 17/615,909

(22) PCT Filed: Jun. 3, 2019
(86) PCT No.: PCT/JP2019/021945

§ 371 Date: Dec. 2, 2021

(51) Int. Cl. H01S 5/32; H01S 5/042

(52) U.S. Cl. CPC H01S 5/32; H01S 5/0422

(57) ABSTRACT

An active region formed on a substrate, and a p-type region and an n-type region formed so as to sandwich the active region are provided. The p-type region and the n-type region are formed so as to sandwich the active region. Both edges of a first side being a side of the p-type region and facing a first side surface of the active region are rounded in a direction separating from the active region. Also, both edges of a second side being a side of the n-type region and facing a second side surface of the active region are rounded in a direction separating from the active region.

### CROSS-REFERENCE TO RELATED APPLICATIONS

This application is a national phase entry of PCT Application No. PCT/JP2019/021945, filed on Jun. 3, 2019, which application is hereby incorporated herein by reference.

### TECHNICAL FIELD

The present disclosure relates to an optical device including an active region.

### BACKGROUND

In a lateral injection type optical semiconductor device, which is represented by a membrane laser, a two-dimensional photonic crystal laser, and the like, an active region is embedded in a thin film. In order to allow current injection into this active region, a p-type doped region and an n-type doped region are formed on both side surfaces of the rectangular active region so as to sandwich the active region from the left and right sides with respect to a waveguide direction (laser emitting direction) in planar view (see Non Patent Literatures (NPL) 1 to 3). Note that the doped regions are fabricated by thermal diffusion or ion implantation.

A shape of the doped region formed in this manner in planar view is rectangular or trapezoidal. In addition, in order to inject a current into the overall active region, a length in the waveguide direction of the doped region in contact with the side surface of the active region is made to be equal to a length in the waveguide direction of the active region (see NPLs 1 to 3).

### CITATION LIST

### Non Patent Literature

NPL 1: S. Matsuo et al., “Directly Modulated Buried Heterostructure DFB Laser on SiO₂/Si Substrate Fabricated by Regrowth of InP Using Bonded Active Layer”, Optics Express, vol. 22, no. 10, pp. 12139-12147, 2014.

NPL 2: S. Matsuo et al., “Room-temperature Continuous-wave Operation of Lateral Current Injection Wavelength-scale Embedded Active-region Photonic-crystal Laser”, Optics Express, vol. 20, no. 4, pp. 3773-3780, 2012.

NPL 3: K. Takeda et al., “Few-fJ/bit Data Transmissions Using Directly Modulated Lambda-scale Embedded Active Region Photonic-crystal Lasers”, Nature Photonics, vol. 7, pp. 569-575, 2013.

### SUMMARY

### Technical Problem

In order to reduce power consumption of the lateral injection laser described above, in planar view, a cuboid active region having a very small volume with a length in the waveguide direction of approximately several μm to several hundreds nm and a width of approximately several hundreds nm is used. In this manner, when the length in the waveguide direction in planar view of the active region is substantially the same as the width of the active region, the active region is not considered to be a uniform system in the waveguide direction, and the influence caused by the edge effect appears.

That is, at an edge portion in the waveguide direction of the active region, band discontinuity occurs between the active region having a smaller band gap and a bulk material having a larger band gap. Thus, electric field concentration is generated at the edge portion described above, and a current density in the periphery of the edge portion of the active region becomes particularly high. This makes non-uniformity of a current density distribution inside the active region, non-uniformity of a carrier density distribution associated with the non-uniformity of the current density distribution, and a sneak leakage current passing through the periphery of the active region remarkable.

A current injection structure of a typical lateral injection type photonic crystal laser will be described with reference to FIGS. 7 and 8. FIGS. 7 and 8 schematically illustrate simulation models. In a lateral injection laser that performs doping by thermal diffusion or ion implantation, in consideration of spread of a distribution in an in-plane direction due to diffusion of a dopant itself in this fabrication process, a non-doped region of approximately several hundreds nm is spaced as a gap between an active region and a doping region at the time of designing.

Consequently, depending on the degree of diffusion of the dopant, each of a p-type region 302 and an n-type region 303 may contact with an active region 301 as illustrated in FIG. 7, or gaps 304 and 305 may be opened between the active region 301 and each of the p-type region 302 and the n-type region 303 as illustrated in FIG. 8.

A simulation result of calculating an electron current distribution in the in-plane direction when a bias voltage in a positive direction of 1.2 V was applied between the p-type region 302 and the n-type region 303 in the structure with no gaps described above is illustrated in FIG. 9. Also, a simulation result of calculating a hole current distribution in the in-plane direction when the bias voltage in the positive direction of 1.2 V was applied between the p-type region 302 and the n-type region 303 in the structure with no gaps described above is illustrated in FIG. 10.

Due to the edge effect described above, for both the electron current and the hole current, it can be seen that the current density specifically increases in the regions, which are surrounded by ellipses in the figures, of the left and right edge portions of the active region. In addition, it can be seen that the edge effect is reflected inside the p-type region and the n-type region that are trapezoidal, and the current density is particularly high at both the right and left edge portions at the tip of the trapezoidal shape. An increase in current density at the edge portion of the p-type region and the edge portion of the n-type region leads to an increase in leakage current passing through the periphery of the active region.

The effect described above is particularly remarkable in a case where the non-doped gap exists between the active region and the doped region, as can be seen from a simulation result of an electron current distribution when a bias voltage of +1.2 V was applied (see FIG. 11), and a simulation result of a hole current distribution when a bias voltage of +1.2 V was applied (see FIG. 12). Note that in FIG. 11 and FIG. 12, the regions surrounded by ellipses are regions in which the current density specifically increases.

Typically, it has been known that non-uniformity of a carrier density in an active region promotes carrier recombination that inhibits induced emission of laser light, such as spontaneous emission recombination or Auger recombination, which leads to a decrease in internal quantum efficiency to degrade the characteristics of laser. Additionally, the occurrence of a leakage current passing through the periphery of the active region described above leads to a decrease in current injection efficiency, and negative effects such as an increase in threshold current and a decrease in maximum output power due to thermal saturation appear.

Thus, in order to efficiently inject a current into a short active region from several um to a sub-μm scale as used in a photonic crystal laser and the like to maximize device characteristics, the edge effect that is generated at the edge portion of the active region is required to be suppressed.

The present disclosure is contrived to solve the above-described problem, and an object thereof is to suppress an edge effect that is generated at an edge portion of an active region.

### Means for Solving the Problem

An optical device according to the present disclosure includes an active region formed on a substrate, and a p-type region and an n-type region formed on the substrate so as to sandwich the active region, in which both edges of a first side being a side of the p-type region and facing the active region are rounded in a direction separating from the active region in planar view, and both edges of a second side being a side of the n-type region and facing the active region are rounded in a direction separating from the active region in planar view.

In one configuration example of the optical device described above, the first side and a third side are connected by a curve in planar view and the first side and a fourth side are connected by a curve in planar view, in which the third side and the fourth side being two sides of the p-type region, sandwiching the first side, and facing each other, and the second side and a fifth side are connected by a curve in planar view and the second side and a sixth side are connected by a curve in planar view, in which the fifth side and the sixth side being two sides of the n-type region, sandwiching the second side, and facing each other.

An optical device according to the present disclosure includes an active region formed on a substrate, and a p-type region and a n-type region formed on the substrate so as to sandwich the active region, in which both edges of a first side surface and a second side surface being side surfaces of the active region and respectively facing the p-type region and the n-type region are rounded respectively in directions separating from the p-type region and the n-type region in planar view.

In one example configuration of the optical device, the active region is oval in planar view.

In the optical device described above, a surface, of the p-type region, facing the active region is formed in contact with the active region, and a surface, of the n-type region, facing the active region is formed in contact with the active region.

The optical device described above further includes a resonator.

### Effects of Embodiments of the Invention

As described above, according to the present disclosure, an edge effect that is generated at an edge portion of an active region can be suppressed.

### BRIEF DESCRIPTION OF THE DRAWINGS

FIG. 1 is a plan view illustrating a configuration of an optical device according to a first embodiment of the present disclosure.

FIG. 2 is a plan view illustrating a configuration of another optical device according to the first embodiment of the present disclosure.

FIG. 3 is computer graphics illustrating a simulation result of an electron current distribution when a bias voltage of 1.2 V is applied to the other optical device according to the first embodiment of the present disclosure.

FIG. 4 is computer graphics illustrating a simulation result of a hole current distribution when the bias voltage of 1.2 V is applied to the other optical device according to the first embodiment of the present disclosure.

FIG. 5 is a plan view illustrating a configuration of an optical device according to a second embodiment of the present disclosure.

FIG. 6 is a plan view illustrating a configuration of another optical device according to the second embodiment of the present disclosure.

FIG. 7 is a plan view illustrating a current injection structure of a typical lateral injection type photonic crystal laser.

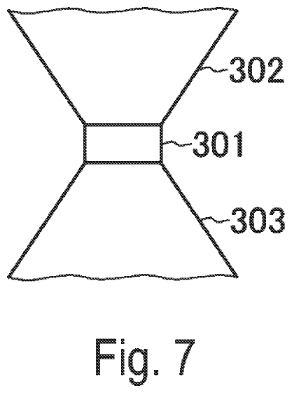

FIG. 8 is a plan view illustrating another current injection structure of a typical lateral injection type photonic crystal laser.

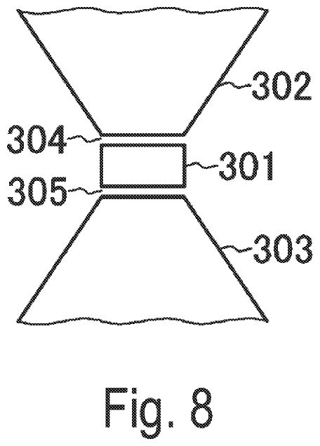

FIG. 9 is computer graphics illustrating a simulation result of calculating an electron current distribution in an in-plane direction when a bias voltage in a positive direction of 1.2 V is applied to the current injection structure of the typical lateral injection type photonic crystal laser illustrated in FIG. 7.

FIG. 10 is computer graphics illustrating a simulation result of calculating a hole current distribution in the in-plane direction when the bias voltage in the positive direction of 1.2 V is applied to the current injection structure of the typical lateral injection type photonic crystal laser illustrated in FIG. 7.

FIG. 11 is computer graphics illustrating a simulation result of calculating an electron current distribution in an in-plane direction when a bias voltage in a positive direction of 1.2 V is applied to the current injection structure of the typical lateral injection type photonic crystal laser illustrated in FIG. 8.

FIG. 12 is computer graphics illustrating a simulation result of calculating a hole current distribution in the in-plane direction when the bias voltage in the positive direction of 1.2 V is applied to the current injection structure of the typical lateral injection type photonic crystal laser illustrated in FIG. 8.

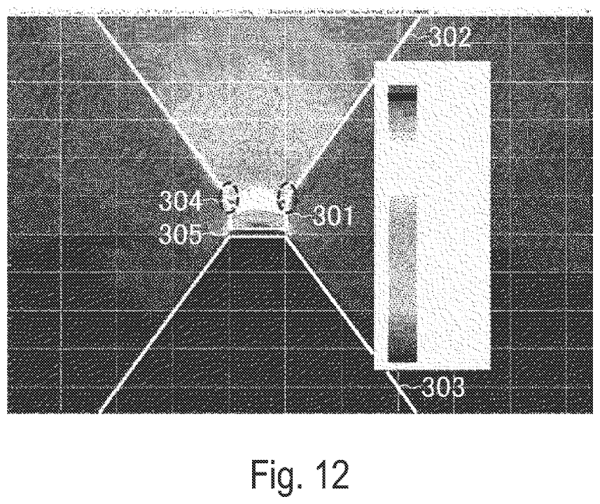

### DETAILED DESCRIPTION OF ILLUSTRATIVE EMBODIMENTS

Hereinafter, optical devices according to embodiments of the present disclosure will be described.

### First Embodiment

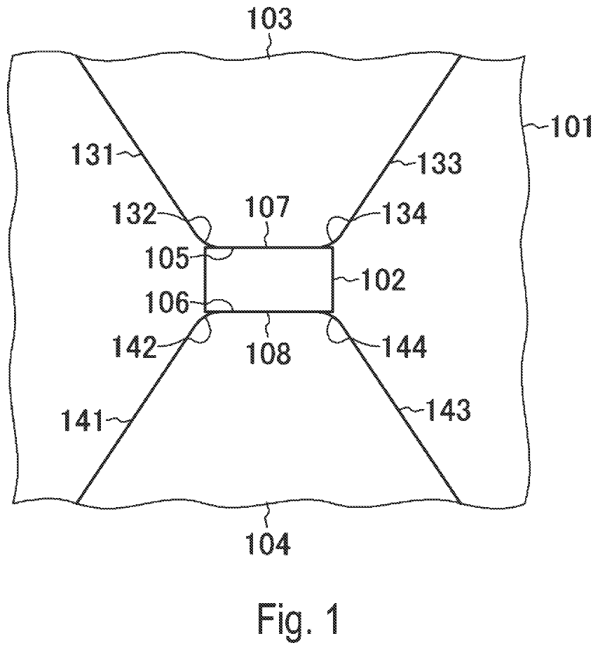

First, an optical device according to a first embodiment of the present disclosure will be described with reference to FIG. 1. The optical device includes an active region 102 formed on the substrate 101, and a p-type region 103 and an n-type region 104 formed so as to sandwich the active region 102. Also, although not illustrated, a resonator is provided so as to sandwich the active region 102.

The substrate 101 is, for example, a well-known photonic crystal, and is composed of, for example, a semiconductor such as InP. The active region 102 is embedded in a line defect waveguide of the photonic crystal, for example. Additionally, the p-type region 103 is a region in which impurities that become p-type are introduced into the photonic crystal by a thermal diffusion method, an ion implantation method, or the like. Furthermore, the n-type region 104 is a region in which impurities that become n-type are introduced into the photonic crystal by a thermal diffusion method, an ion implantation method, or the like.

Hereinafter, shapes in planar view of the active region 102, the p-type region 103, and the n-type region 104 of the optical device according to the first embodiment will be described in more detail. The active region 102 has a first side surface 105 and a second side surface 106 and is formed in a rectangular shape. In the first embodiment, the first side surface 105 and the second side surface 106 are formed along a waveguide direction. Additionally, the p-type region 103 and the n-type region 104 are formed so as to sandwich the active region 102 in directions of the first side surface 105 and the second side surface 106. Additionally, in this example, a surface, of the p-type region 103, facing the active region 102 (first side surface io5) is formed in contact with the active region 102 (first side surface 105). In addition, a surface, of the n-type region 104, facing the active region 102 (second side surface 106) is formed in contact with the active region 102 (second side surface 106).

Also, both edges of a first side 107 being a side of the p-type region 103 and facing the active region 102 are rounded in a direction separating from the active region 102. Also, both edges of a second side 108 being a side of the n-type region 104 and facing the active region 102 are rounded in a direction separating from the active region 102.

Here, in the p-type region 103, two sides being a third side 131 and a fourth side 133, sandwiching the first side 107, and facing each other are inclined in directions in which a width between the two sides increases as the two sides separate farther from the first side 107. In other words, each of an angle formed by the first side 107 and the third side 131, and an angle formed by the first side 107 and the fourth side 133 is an obtuse angle. The first side 107 and the third side 131 of the p-type region 103 configured in this manner are connected by a curve 132, and the first side 107 and the fourth side 133 of the p-type region 103 configured in this manner are connected by a curve 134. In other words, the p-type region 103 has a substantially trapezoidal shape in which an upper base having a shorter length serves as the first side 107, and the third side 131 and the fourth side 133 serve as legs.

In addition, in the n-type region 104, two sides being a fifth side 141 and a sixth side 143, facing each other, and sandwiching the second side 108 are inclined in directions in which a width between the two sides increases as the two sides separate farther from the second side 108. In other words, each of an angle formed by the second side 108 and the fifth side 141, and an angle formed by the second side 108 and the sixth side 143 is an obtuse angle. The second side 108 and the fifth side 141 of the n-type region 104 configured in this manner are connected by a curve 142, and the second side 108 and the sixth side 143 of the n-type region 104 configured in this manner are connected by a curve 144. In other words, the n-type region 104 has a substantially trapezoidal shape in which an upper base having a shorter length serves as the second side 108, and the fifth side 141 and the sixth side 143 serve as legs.

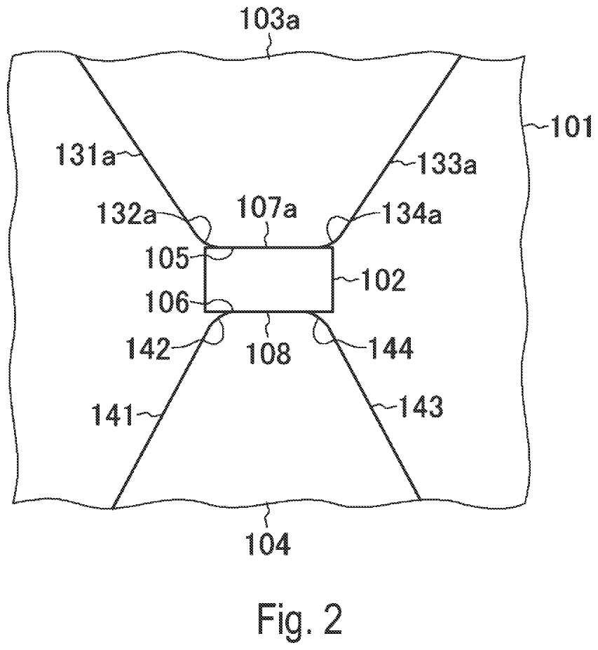

Incidentally, in the description described above, the shape of the p-type region 103 and the shape of the n-type region 104 are symmetrical with respect to each other, but these are not necessarily symmetrical. For example, as illustrated in FIG. 2, a first side 107a being a side of a p-type region 103a and facing the first side surface 105 can be made longer than the second side 108, the p-type region 103a can be made wider than the n-type region 104, and a resistance value of the p-type region 103a typically having a higher resistance can be reduced.

Here, in the p-type region 103a, two sides being a third side 131a and a fourth side 133a, sandwiching the first side 1o7a, and facing each other are inclined in directions in which a width between the two sides increases as the two sides separate farther from the first side 107a. In other words, each of an angle formed by the first side 107a and the third side 131a, and an angle formed by the first side 107a and the fourth side 133a is an obtuse angle. The first side 107a and the third side 131a of the p-type region io3a configured in this manner are connected by a curve 132a, and the first side 107a and the fourth side 133a of the p-type region 103a configured in this manner are connected by a curve 134a. In other words, the p-type region 103a has a substantially trapezoidal shape in which an upper base having a shorter length serves as the first side 107a, and the third side 131a and the fourth side 133a serve as legs.

For example, as is well known, a resist pattern having an opening at a position to be formed with the p-type region 103 is formed on the substrate 101 by a well-known lithographic technique, and ion implantation can be selectively performed by using this resist pattern as a mask to form the p-type region 103. In addition, a p-type layer containing a high concentration of p-type impurities can be formed at the position to be formed with the p-type region 103 on the substrate 101 by a well-known lithographic technique, and thus, the p-type region 103 can be formed by thermal diffusion. The same applies to the n-type region.

In the design stage of the mask to be used in the lithographic technique described above, each of the p-type region 103 and the n-type region 104 having the shape described above can be formed, in consideration of the effect of dopant diffusion by thermal diffusion or ion implantation, by reducing the opening of the resist pattern inward from the final shape by the amount of the diffusion.

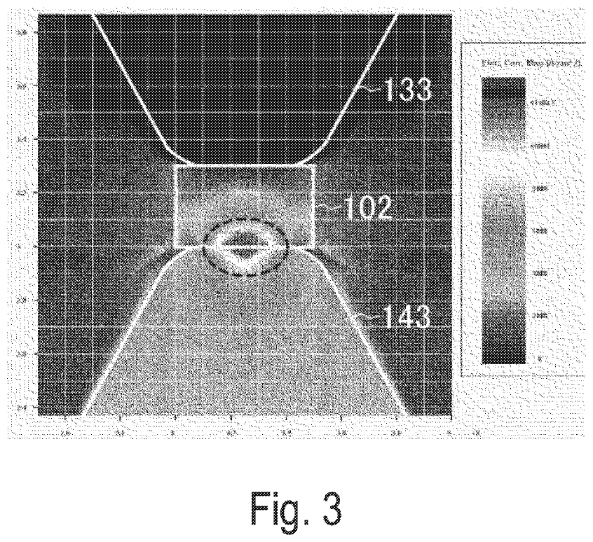

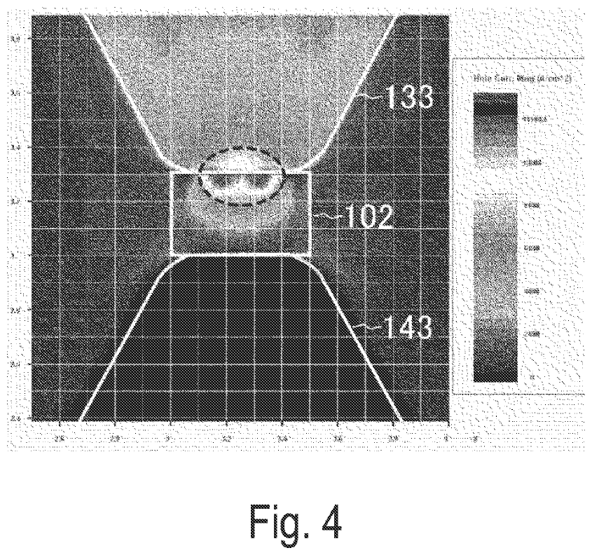

Next, in the optical device according to the first embodiment, a simulation result of an electron current distribution when a bias voltage of 1.2 V was applied to the p-type region 103 and the n-type region 104 is illustrated in FIG. 3. Also, in the optical device according to the first embodiment, a simulation result of a hole current distribution when the bias voltage of 1.2 V was applied to the p-type region 103 and the n-type region 104 is illustrated in FIG. 4.

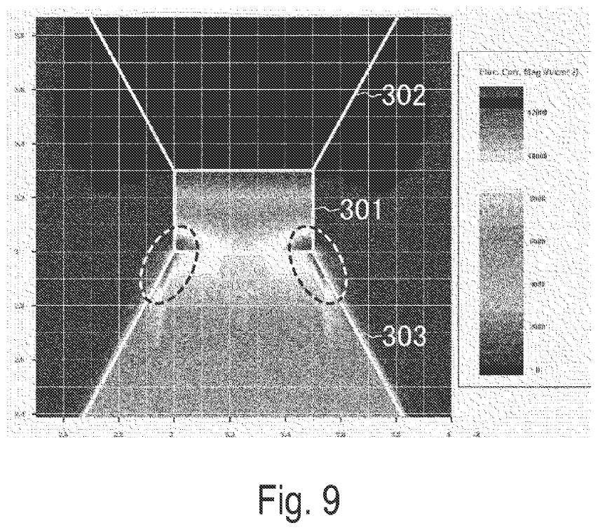

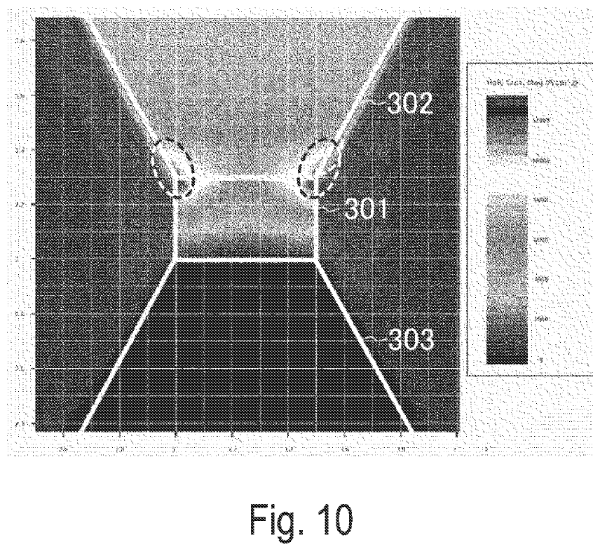

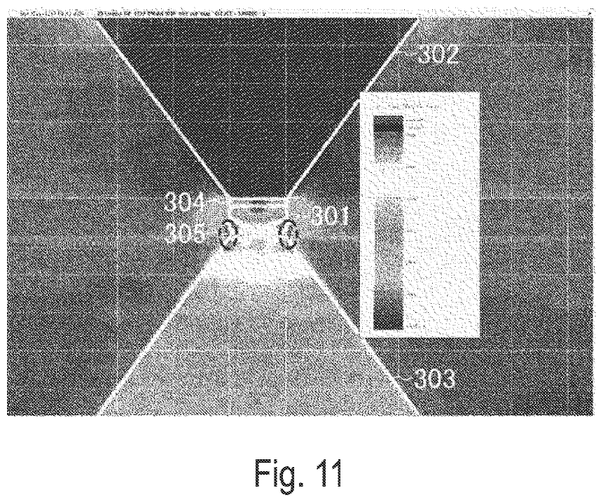

As illustrated in FIGS. 3 and 4, it can be seen that the edge effect is suppressed by spacing the p-type region and the n-type region at the edge portions of the active region, and as illustrated in the regions indicated by the ellipses in the figures, current injection occurs into the overall portions where the p-type region and the n-type region contact with the active region. Also, when attention is focused on the current distributions in the p-type region and the n-type region, it can be seen that by smoothly rounding the edge portions of the trapezoidal shape and separating each of the p-type region and the n-type region from the edge portion of the active region, the current density concentration at the edge portion of the active region as illustrated in FIGS. 9 to 11 is suppressed, and the current gathers throughout the upper side of the trapezoidal shape. This effect suppresses the occurrence of a leakage current sneaking around the periphery of the active region.

Incidentally, concerning a well-known photonic crystal laser, wavelength-scale light confinement is possible, so a length in a waveguide direction of an active region can be shortened to several hundreds nm that is substantially the same degree as a width of the active region. For example, in NPLs 2 and 3, a structure in which an active region is embedded in a line defect waveguide of a two-dimensional photonic crystal is used. In this structure, it is conceivable that in order to achieve reduction of a resistance value in a p-type region and an n-type region, each of the p-type region and the n-type region is formed in a waveguide direction of a line defect waveguide region that does not have holes, that is, the active region, rather than a region having holes of the photonic crystal. In a case of such a configuration, when the configuration according to the first embodiment is applied, a similar effect to that described above can be achieved.

### Second Embodiment

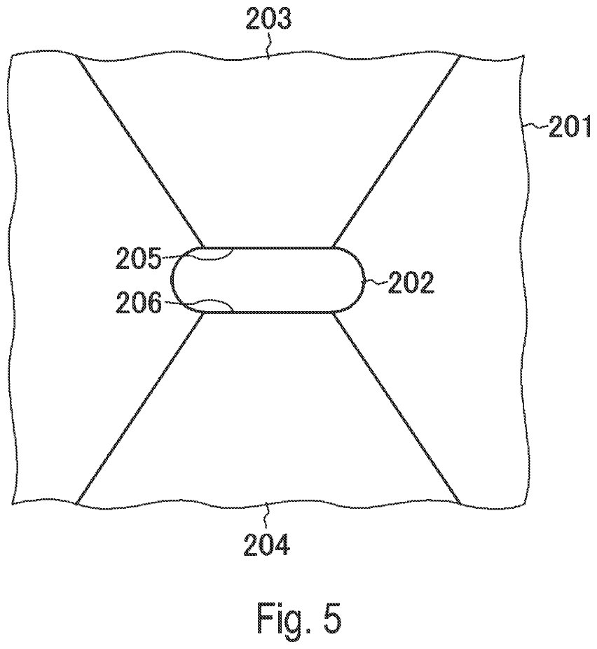

Next, an optical device according to a second embodiment of the present disclosure will be described with reference to FIG. 5. The optical device includes an active region 202 formed on a substrate 201, and a p-type region 203 and an n-type region 204 formed so as to sandwich the active region 202. Also, although not illustrated, a resonator is provided so as to sandwich the active region 202.

The substrate 201 is, for example, a well-known photonic crystal, and is composed of, for example, a semiconductor such as InP. The active region 202 is embedded in a line defect waveguide of the photonic crystal, for example. Additionally, the p-type region 203 is a region in which impurities that become p-type are introduced into the photonic crystal by a thermal diffusion method, an ion implantation method, or the like. Furthermore, the n-type region 204 is a region in which impurities that become n-type are introduced into the photonic crystal by a thermal diffusion method, an ion implantation method, or the like.

Hereinafter, shapes in planar view of the active region 202, the p-type region 203, and the n-type region 204 of the optical device according to the second embodiment will be described in more detail.

The active region 202 has a first side surface 205 and a second side surface 206, and is formed in a rectangular shape. In the second embodiment, the first side surface 205 and the second side surface 206 are formed along a waveguide direction. Additionally, the p-type region 203 and the n-type region 204 are formed so as to sandwich the active region 202 in directions of the first side surface 205 and the second side surface 206. Additionally, in this example, a surface, of the p-type region 203, facing the active region 202 (first side surface 205) is formed in contact with the active region 202, and a surface, of the n-type region 204, facing the active region 202 (second side surface 206) is formed in contact with the active region 202.

In addition, in the optical device according to the second embodiment, both edges of the first side surface 205 and the second side surface 206 being side surfaces of the active region 202 and respectively facing the p-type region 203 and the n-type region 204 are rounded respectively in directions separating from the p-type region 203 and the n-type region 204. For example, the active region 202 is oval in planar view. The active region 202 having such a shape can be implemented by making a mask shape of a photomask that is used in lithography for forming the active region 202 similar to the shape to be fabricated.

Note that in this example, a surface, of the p-type region 203, facing the active region 202 (first side surface 205) is formed in contact with the active region 202, and a surface, of the n-type region 204, facing the active region 202 (second side surface 206) is formed in contact with the active region 202. In addition, in the second embodiment, the p-type region 203 has a substantially trapezoidal shape in which a side facing the active region 202 serves as an upper base having a shorter length, and two sides connected to the side serve as legs. The same applies to the n-type region 204.

Typically, a rectangular active region in planar view is used, but in the second embodiment, shapes of edge portions in a waveguide direction are curves rather than straight lines, and these curves are smoothly connected with straight lines of the side surfaces along the waveguide direction. A specific shape of the curve may be an arc in planar view, and it is only required that the shape is a smooth curve so as not to generate an indifferentiable portion (that is, a corner) in an outline of the active region 202. Note that the p-type region 203 and the n-type region 204 can have a shape in which the edge portions at the active region 202 side have corners.

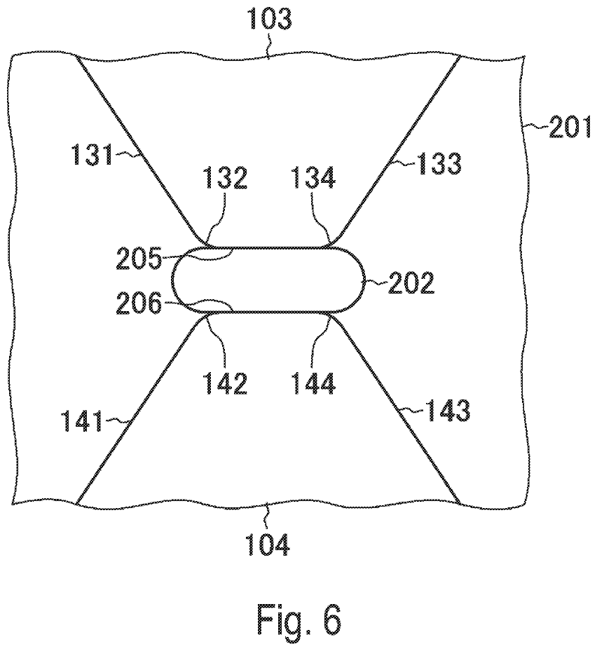

In addition, as illustrated in FIG. 6, the first side 107 and the third side 131 of the p-type region 103 are connected by the curve 132, and the first side 107 and the fourth side 133 are connected by the curve 134. Similarly, the second side 108 and the fifth side 141 of the n-type region 104 are connected by the curve 142, and the second side 108 and the sixth side 143 are connected by the curve 144. These configurations are similar to those of the first embodiment described above.

According to the second embodiment, there are no corners in the shape of the active region 202 in planar view, so the edge effect is suppressed. In addition, the current concentration on the entire sides, at the active region 202 side, of the p-type region 203 and the n-type region 204 can be achieved to more effectively inject a current.

Incidentally, concerning a well-known photonic crystal laser, wavelength-scale light confinement is possible, so a length in the waveguide direction of an active region can be shortened to several hundreds nm that is substantially the same degree as a width of the active region. For example, in NPLs 2 and 3, a structure in which an active region is embedded in a line defect waveguide of a two-dimensional photonic crystal is used. In this structure, it is conceivable that in order to achieve reduction of a resistance value in a p-type region and an n-type region, each of the p-type region and the n-type region is formed in a waveguide direction of a line defect waveguide region that does not have holes, that is, the active region, rather than a region having holes of the photonic crystal. In a case of such a configuration, when the configuration according to the second embodiment is applied, a similar effect to that described above can be achieved.

As described above, in the present disclosure, both edges of the first side being a side of the p-type region and facing the active region are rounded in the direction separating from the active region, and both edges of the second side being a side of the n-type region and facing the active region are rounded in the direction separating from the active region. Additionally, in the present disclosure, both edges of the first side surface and the second side surface being side surfaces of the active region and respectively facing the p-type region and the n-type region are rounded respectively in the directions separating from the p-type region and the n-type region. As a result, according to the present disclosure, the edge effect that is generated at the edge portions of the active region can be suppressed.

The present disclosure focuses on the mechanism of laser performance degradation to which attention has not been paid, and that is referred to as the edge effect derived from the shape of the active region. The present disclosure achieves elimination of the non-uniformity of a current density distribution and reduction in leakage current in the periphery of the active region by appropriately controlling the shape of the p-type region and the shape of the n-type region near the active region, and the shape of the active region in order to resolve the laser performance degradation.

The present disclosure is not limited to the embodiments described above, and it is obvious that many modifications and combinations can be implemented by a person having ordinary knowledge in the field within the technical spirit of the present disclosure.

### REFERENCE SIGNS LIST

101 Substrate

102 Active region

103 p-type region

104 n-type region

105 First side surface

106 Second side surface

107 First side

108 Second side

131 Third side

132 Curve

133 Fourth side

134 Curve

141 Fifth side

142 Curve

143 Sixth side

144 Curve.

1-6. (canceled)

7. An optical device, comprising:
an active region on a substrate; and
a p-type region and an n-type region on the substrate and sandwiching the active region,
wherein edges of a first side of the p-type region are rounded in a direction separating from the active region in a planar view, the first side of the p-type region facing the active region, and
wherein edges of a second side of the n-type region are rounded in a direction separating from the active region in the planar view, the second side of the n-type region facing the active region.

8. The optical device according to claim 7, wherein:
the first side and a third side of the p-type region are connected by a curve in the planar view;
the first side and a fourth side of the p-type region are connected by a curve in the planar view, the third side and the fourth side sandwiching the first side and facing each other;
the second side and a fifth side of the n-type region are connected by a curve in the planar view; and
the second side and a sixth side of the n-type region are connected by a curve in the planar view, the fifth side and the sixth side sandwiching the second side and facing each other.

9. The optical device according to claim 7, wherein:
the first side of the p-type region is in contact with the active region; and
the second side of the n-type region is in contact with the active region.

10. The optical device according to claim 7, further comprising a resonator.

11. An optical device, comprising:
an active region on a substrate; and
a p-type region and an n-type region on the substrate and sandwiching the active region,
wherein edges of a first side surface of the active region are rounded in a direction separating from the p-type region in a planar view, the first side surface of the active region facing the p-type region, and
wherein edges of a second side surface of the active region are rounded in a direction separating from the n-type region in the planar view, the second side surface of the active region facing the n-type region.

12. The optical device according to claim 1,
wherein the active region is ovular in planar view.

13. The optical device according to claim 11, wherein:
a surface of the p-type region facing the active region is in contact with the active region; and
a surface of the n-type region facing the active region is in contact with the active region.

14. The optical device according to claim ii, further comprising a resonator.
